(19) United States
(12) Patent Application Publication
(10) Pub. No.: US 2018/0033960 A1
(43) Pub. Date: Feb. 1, 2018

(54) NONVOLATILE MEMORY ELEMENTS HAVING CONDUCTIVE STRUCTURES WITH SEMIMETALS AND/OR SEMICONDUCTORS

(71) Applicant: Adesto Technologies Corporation, Santa Clara, CA (US)

(72) Inventors: John Ross Jameson, III, Menlo Park, CA (US); Foroozan Sarah Koushan, San Jose, CA (US)

(21) Appl. No.: 15/650,719

(22) Filed: Jul. 14, 2017

Related U.S. Application Data
(63) Continuation-in-part of application No. 14/217,256, filed on Mar. 17, 2014, now Pat. No. 9,711,719.
(60) Provisional application No. 62/492,050, filed on Apr. 28, 2017.
(60) Provisional application No. 61/798,919, filed on Mar. 15, 2013.

(51) Int. Cl. H01L 45/00

(52) U.S. Cl. CPC H01L 45/1253; H01L 45/146; H01L 45/16

(57) ABSTRACT

A memory element programmable between different impedance states, comprising: a first electrode layer comprising a semimetal or semiconductor (semimetal/semiconductor) and at least one other first electrode element; a second electrode; and a switch layer formed between the first and second electrodes and comprising an insulating material; wherein atoms of the semimetal/semiconductor provide a reversible change in conductivity of the switch layer by application of electric fields.

This application claims the benefit of provisional patent application serial no. 62/492,050, filed on Apr. 28, 2017, and is a continuation-in-part of U.S. patent application Ser. No. 14/217,256 filed Mar. 17, 2014, which claims the benefit of provisional patent application Ser. No. 61/798,919, filed on Mar. 15, 2013, the contents all of which are incorporated by reference herein.

### TECHNICAL FIELD

The present disclosure relates generally to memory elements, and more particularly to memory elements programmable between two or more impedance states in response to the application of electric fields.

### BACKGROUND

There is a need to store information for long periods of time without the use of power. For example, in many electronic devices and systems, data can be stored in a nonvolatile memory, or quasi-nonvolatile memory. A quasi-nonvolatile memory can be a memory with a ‘refresh’ interval order of magnitude longer than a dynamic random access memory (DRAM).

One type of memory is a conductive bridging random access memory (CBRAM). A CBRAM can have memory elements that store information in terms of the resistance level of two-terminal structure, which can include a metal/insulator/metal structure. A change in resistance can come about by the creation and destruction of a conductive pathway made mostly or, more commonly, entirely of metal atoms.

### BRIEF DESCRIPTION OF THE DRAWINGS

FIG. 1 is a side cross sectional view of a memory element according to an embodiment.

FIGS. 2A to 2C are side cross sectional views showing the formation of conductive regions within a switch layer of a memory element according to an embodiment.

FIGS. 3A to 3D are side cross sectional views showing the formation of conductive regions within a switch layer of a memory element according to another embodiment.

FIGS. 4A to 4C are side cross sectional views showing the formation of conductive regions within a switch layer of a memory element according to another embodiment.

FIG. 5 is a side cross sectional view of a memory element according to another embodiment.

FIG. 6 is a side cross sectional view of a memory element according to another embodiment.

FIG. 7 is a side cross sectional view of a memory element according to another embodiment.

FIG. 8 is a side cross sectional view of a memory element according to another embodiment.

FIGS. 9A to 9C are side cross sectional views showing the formation of a memory element according to an embodiment.

FIGS. 10A and 10B are side cross sectional views showing the formation of a memory element according to another embodiment.

FIGS. 11A to 11C are side cross sectional views showing the formation of a memory element according to a further embodiment.

### DETAILED DESCRIPTION

According to embodiments, a memory element can include a memory cell that utilizes a semiconductor or semimetal (including metalloids) to form a conductive pathway through an insulating switch layer.

In some embodiments, a memory element can have a structure like that of a conventional conductive bridging random access memory (CBRAM) element, however the creation and destruction of a conductive pathway may include a semimetal or semiconductor. That is, reversible conductive pathways can be formed all, or in part, by a semimetal or semiconductor. In some embodiments, a conductive pathway may not include metal atoms, or a majority of a conductive pathway can be formed by semimetal/semiconductor atoms.

Compared to a conventional metal-based CBRAM cell, a conductive pathway formed by a semimetal or semiconductor may include more atoms to be present in the conductive pathway to achieve a comparably low resistance level, making such a conductive pathway less susceptible to on-state retention failures (i.e., unwanted, spontaneous transitions from low resistance to high resistance).

Additionally, for a programming operation which produces a conductive path of a given “width” (e.g., 1, 2, or 3 atoms), a conductive pathway based on a semimetal or semiconductor may have a resistance substantially higher than a comparable path based on a metal (e.g., ˜100 kΩ for a bismuth (Bi) pathway with a 1-atom constriction vs. ˜10 kΩ for a copper Cu pathway with a 1-atom constriction). This can lead to lower current and/or power requirements for programming and/or erase than conventional CBRAM cells.

While some conventional CBRAM elements can attain their low resistance by electrically introducing metal atoms into the insulating layer dispersed between the two electrodes, in others, a metal oxide is often used as the insulating layer, and the low-resistance state is often said to arise from the presence of metal atoms that remain after oxygen has been removed from some region of the metal oxide. For example, titanium (Ti) atoms can remain after (oxygen) (O) has been removed from a titanium oxide (TiO₂) layer. Thus, in both conventional cases, the low-resistance state may be ascribed to the presence of metal atoms. In sharp contrast, according to embodiments herein, a low-resistance state (or a significant portion of the low resistance state) may be ascribed to the present of semimetal and/or semiconductor atoms, not metal atoms.

According to particular embodiments, a memory cell can include a first electrode (which can be referred to as an anode), a second electrode (which can be referred to as a cathode), and an insulating layer dispersed between the two. The anode can include one or more semimetals (e.g., Bi) and/or one or more semiconductors (e.g., Si). Such a semimetal or semiconductor can also include any of the following: an element which is a semimetal or semiconductor in at least one of its possible crystal phases (e.g., Te, which has a high-pressure metallic form and a low-pressure semiconductor form with a bandgap of 0.3 eV); an element which may become semimetallic or semiconducting upon reduction to nano-scale or atomic-scale dimensions; or an alloy or other compound containing one or more such elements (e.g., TiTeₓ).

An anode may serve as a source of those atoms that can form one or more conductive pathways in the insulating layer (i.e., conductive pathways formed, at least in part, by a semimetal or semiconductor). Additional conductive layers may be present on top of the anode or below the cathode to aid in fabrication or in operation of the circuit used to control the cell (e.g., to lower the resistance of the connection to the cell).

One or more electrical pulses can be applied between the two electrodes to cause the semimetal or semiconductor atoms to form a conductive pathway. One or more electrical pulse different in magnitude or polarity could be used to disrupt this conductive pathway to return the device to a higher resistance state. An initial “forming” electrical pulse may be applied to an as-fabricated device to introduce the semimetal or semiconductor atoms into the insulating layer, with the subsequent program or erase operations causing the semimetal or semiconductor atoms to rearrange into low-resistance or high-resistance pathways, respectively.

In addition or alternatively, the semimetal or semiconductor atoms may be introduced and removed from the insulating layer with each program/erase cycle of the device.

In addition or alternatively, the semimetal or semiconductor atoms can be introduced into the insulating layer by an initial thermal or chemical treatment, instead of an electrical pulse, and program/erase electrical pulses used to rearrange the atoms to form a low-, high-resistance pathways, respectively.

In addition or alternatively, the semimetal or semiconductor atoms can be introduced into the insulating layer in situ, as the insulating layer is formed.

Embodiments can include memory device architectures like those of conventional CBRAM devices (including resistive RAM (RRAM) devices), but include memory elements as described herein. As a result, memory devices according to embodiments can have programming power supply voltages and/or durations that may be less than those of such conventional devices. Memory devices according to embodiments can have greater wear cycles, or greater time periods between “reconditioning” type operations than conventional memory devices. Reconditioning type operations can be operations that reprogram elements into particular states (e.g., tighten resistance distributions, program the cells after erasing/programming all the cells to a same state). Memory devices according to embodiments can have wear algorithms that allow for a larger number of cycles before data are shifted between different memory blocks, or the like.

In the embodiments disclosed herein, like sections are referred to by the same reference character but with the leading digit(s) corresponding to the

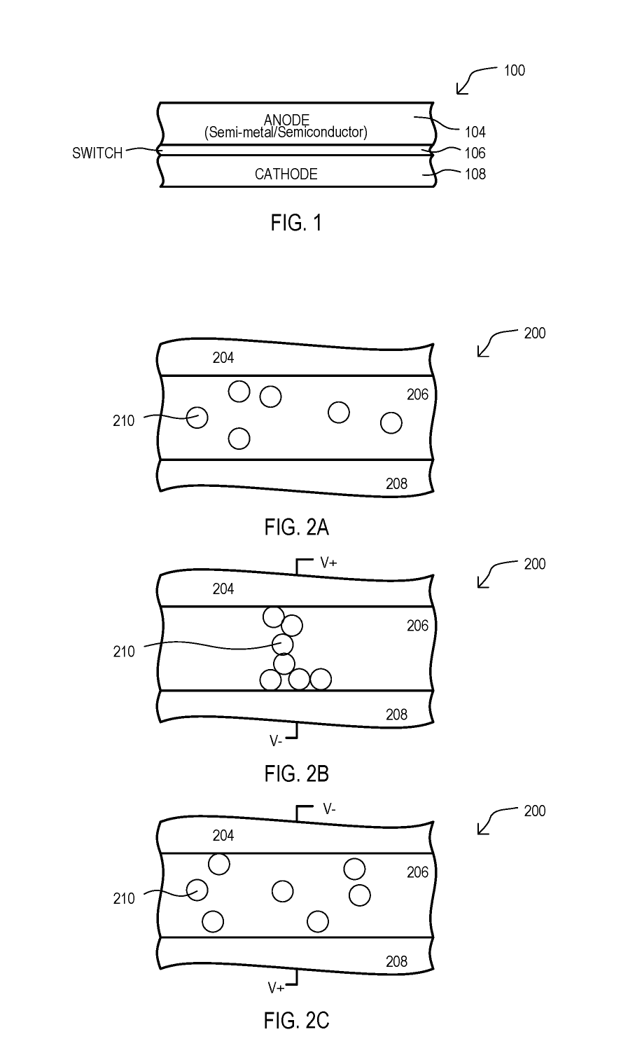

FIG. 1 is a side cross sectional representation of a memory element 100 according to an embodiment. A memory cell can include a first electrode 104, a switch layer 106, and a second electrode 108. In some embodiments, a first electrode 104 can include one or more semimetals or semiconductors. Such semimetals and/or semiconductors can include any of: carbon (C), tellurium (Te), antimony (Sb), arsenic (As), germanium (Ge), silicon (Si), bismuth (Bi), tin (Sn), sulfur (S), or selenium (Se), for example.

A switch layer 106 can be formed between first and second electrodes 104/108. A switch layer 106 can be formed of a material that can switch its conductivity by application of electric fields across the electrodes. According to embodiments, a switch layer 106 can be an insulating material in which conductive pathways can be formed and unformed by application of electric fields. Such conductive pathways can be formed, at least in part, from one or more semimetals and/or semiconductors (semimetal(s)/semiconductor(s)). In some embodiments, a switch layer 106 may have essentially none of the pathway forming semimetal(s)/semiconductor(s), with an anode 104 being the source of substantially all of the semimetal(s)/semiconductor(s). However, in other embodiments, a switch layer 106 may include some of the semimetal(s)/sem iconductor(s), with an anode 104 contributing additional amounts of the semimetal(s)/semiconductor(s). In still other embodiments, a switch layer 106 may include the semimetal(s)/semiconductor(s)/with an anode 104 contributing none, or very little of its semimetal(s)/ semiconductor(s) in the formation of conductive pathways within switch layer 106.

In some embodiments, a switch layer 106 can be a metal oxide. In particular embodiments, a switch layer 106 can be a binary metal oxide. In very particular embodiments, a switch layer 106 can include any of: aluminum oxide (AlₓO_{y}), calcium oxide (CaₓO_{y}), gadolinium oxide (GdₓO_{y}), germanium oxide (GeₓO_{y}), hafnium oxide (HfₓO_{y}), lutetium oxide (LuₓO_{y}), magnesium oxide (MgₓO_{y}), molybdenum oxide (MoₓO_{y}), niobium oxide (NbₓO_{y}), scandium oxide (ScₓO_{y}), silicon oxide (SiₓO_{y}), strontium oxide (SrₓO_{y}), tantalum oxide (TaₓO_{y}), titanium oxide (TiₓO_{y}), vanadium oxide (VₓO_{y}), tungsten oxide (WₓO_{y}), yttrium oxide (YₓO_{y}), and/or zirconium oxide (ZrₓO_{y}). It is understood that such metal oxides can have stoichiometric or non-stoichiometric forms.

For some particular embodiments, metal oxide can have the following stoichiometries. For calcium oxide (CaₓO_{y}), magnesium oxide (MgₓO_{y}) and strontium oxide (SrₓO_{y}), x and y can be about 1. For aluminum oxide (AlₓO_{y}), lutetium oxide (LuₓO_{y}), scandium oxide (ScₓO_{y}) and yttrium oxide (YₓO_{y}), where x can be about 2, y can be about 3. For germanium oxide (GeₓO_{y}), hafnium oxide (HfₓO_{y}), titanium oxide (TiₓO_{y}), zirconium oxide (ZrₓO_{y}), x can be about 1, y can be about 2. For niobium oxide (NbₓO_{y}), tantalum oxide (TaₓO_{y}), and vanadium oxide (VₓO_{y}), x can be about 2 and y can be about 5. For molybdenum oxide (MoₓO_{y}) and tungsten oxide (WₓO_{y}), x can be about 1, y can be about 3.

In some embodiments, a first electrode 104 can include one or more semimetal(s)/semiconductor(s) and one or more other elements. In particular embodiments, a first electrode 104 can be a binary alloy of the semimetal(s)/semiconductor(s) and another metal element. A metal of the first electrode 104 used in combination with the semimetal(s)/semiconductor(s) can be a transition metal. In some embodiments, such a metal can be a rare earth metal. However, in other embodiments, such a metal may not be a transition metal (and hence not a rare earth metal, either).

In particular embodiments, a first electrode 104 can be a binary alloy of Te (with Te being the semimetal/semiconductor). In such a binary alloy, the other element of the alloy can be selected from Al, Hf, Lu, Mg, Mo, Nb, Sc, Sr, Ta, Ti, V, W, Y, Zr, as well as gold (Au), barium (Ba), bromine (Br), cadmium (Cd), cerium (Ce), cobalt (Co), chromium (Cr), dysprosium (Dy), erbium (Er),europium (Eu), iron (Fe), gallium (Ga), gadolinium (Gd), holmium (Ho), indium (In), iridium (Ir), lanthanum (La), manganese (Mn), nickel (Ni), lead (Pb), palladium (Pd), praseodymium (Pr), platinum (Pt), rubidium (Rb), rhenium (Re), ruthenium (Ru), rhodium (Rh), samarium (Sm), strontium (Sr) and thallium (Tl).

In some embodiments, a first electrode can be an alloy of zirconium (Zr) and Te, or an alloy of Ti and Zr, or an alloy of Hf and Te. Further, a corresponding switch layer 106 can be ZrOx, TiOx, or HfOx, respectively.

In some particular embodiments, a first electrode 104 can be an alloy of Te and Sc, Ta, W, Y or Lu. In such embodiments, a first electrode 104 can be about 25-75 atomic percent of (Sc, Ta, W, Y or Lu) and about 0.33-3.0 atomic percent of Te.

In other particular embodiments, a first electrode 104 can be an alloy of Te and Ti, Zr or Hf. In such embodiments, a first electrode 104 can be about 25-75 atomic percent of (Ti, Zr or Hf), more preferably about 30-60 atomic percent. Te can be present at about 0.33-3.0 atomic percent, more particularly 0.43-1.5 atomic percent.

In further particular embodiments, a first electrode 104 can be an alloy of Te and V or Nb. In such embodiments, a first electrode 104 can be about 25-75 atomic percent of (V or Nb), more preferably about 40-60 atomic percent. Te can be present at about 0.33-3.0 atomic percent, more particularly 0.67-1.5 atomic percent.

In additional particular embodiments, a first electrode 104 can be an alloy of Te and Cr or Mo. In such embodiments, a first electrode 104 can be about 25-75 atomic percent of (Cr or Mo), more preferably about 30-50 atomic percent. Te can be present at about 0.33-3.0 atomic percent, more particularly 0.43-1.0 atomic percent.

In some embodiments, an oxide of a switch layer can be an oxide of an element included in a first electrode. In a very particular embodiment, the switch layer can include a metal oxide and the first anode can include the metal of that metal oxide.

A second electrode 108 can be a conductive material suitable for a desired resistance, or process compatibility, etc. As but one very particular embodiment, a second electrode 108 can be formed of tantalum (Ta).

FIGS. 2A to 2C are side cross sectional views representing the formation of a conductive region with a semimetal(s)/sem iconductor(s) according to embodiments. In a very particular embodiment, FIGS. 2A to 2C show formation operations for a memory element like that shown in FIG. 1.

FIG. 2A shows semimetal(s)/semiconductor(s) 210 within an insulating switch layer 206. In particular embodiments, 210 can represent atoms of semimetal(s)/semiconductor(s) element.

FIG. 2B shows the application of an electric field across the electrodes 204/208 of a first polarity. In response, conductive structures can be formed in the insulator material 206, changing the conductivity of the insulator material 206. Such conductive structures can be formed entirely of one or more semimetal(s)/semiconductor(s) atoms, or include a mix of semimetal(s)/semiconductor(s) atoms and other atom species.

FIG. 2C shows the application of an electric field across the electrodes 204/208 of a second polarity. In response, conductive structures can be removed.

It is understood that FIGS. 2A to 2C are but diagrammatic representations of operation. Actual position or states of semimetal(s)/sem iconductor(s) atoms can take various forms. In some embodiments, portions, or all of a conductive structure may not move, but application of electric fields can change a state of the semimetal(s)/semiconductor(s) atoms and/or compounds.

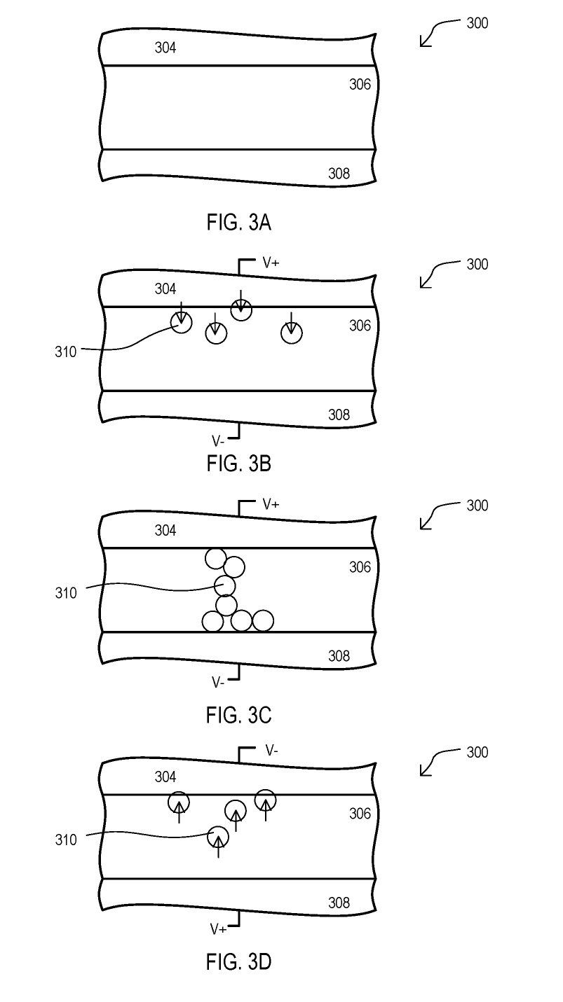

FIGS. 3A to 3D are side cross sectional views representing the formation of a conductive regions within a memory element according to another embodiment. The embodiment of FIGS. 3A-3D shows an arrangement in which a semimetal(s)/semiconductor(s) can originate from an electrode 304 (e.g., anode) and move into switch layer 306. In a very particular embodiment, FIGS. 3A to 3D show formation operations for a memory element like that shown in FIG. 1.

FIG. 3A shows a memory element prior to the application of an electric field. Very little or none of the semimetal(s)/semiconductor(s) that form a conductive structure within the switch layer can be present in the switch layer 306.

FIG. 3B shows the application of an electric field across the electrodes 304/308 of a first polarity. In response, semimetal(s)/sem iconductor(s) 310 can move out of the first electrode 304 (i.e., anode) into the switch layer 306. As in the case above, 310 can represent semimetal(s)/semiconductor(s) atoms, but in other embodiments, semimetal(s)/semiconductor(s) can be compounds of more than one atom.

FIG. 3C shows the continued application of the electric field of FIG. 3B, or a subsequent application of the same electric field. In response to the electric field, the semimetal(s)/sem iconductor(s) 310 that originated from first electrode 304 can form a conductive structure in the insulator material 306. Such conductive structures can be formed entirely of one or more semimetal(s)/semiconductor(s) atoms, or include a mix of semimetal(s)/semiconductor(s) atoms and other atom species.

FIG. 3D shows the application of an electric field across the electrodes 304/308 of a second polarity. In response, conductive structures can be removed. In some embodiments, substantially all or a majority of the semimetal(s)/semiconductor(s) 310 can return to the first electrode 304, or migrate to a position in close proximity of the first electrode 304. However, in other embodiments, a portion of the semimetal(s)/semiconductor(s) 310 that originated from the first electrode 304 can remain in the switching layer.

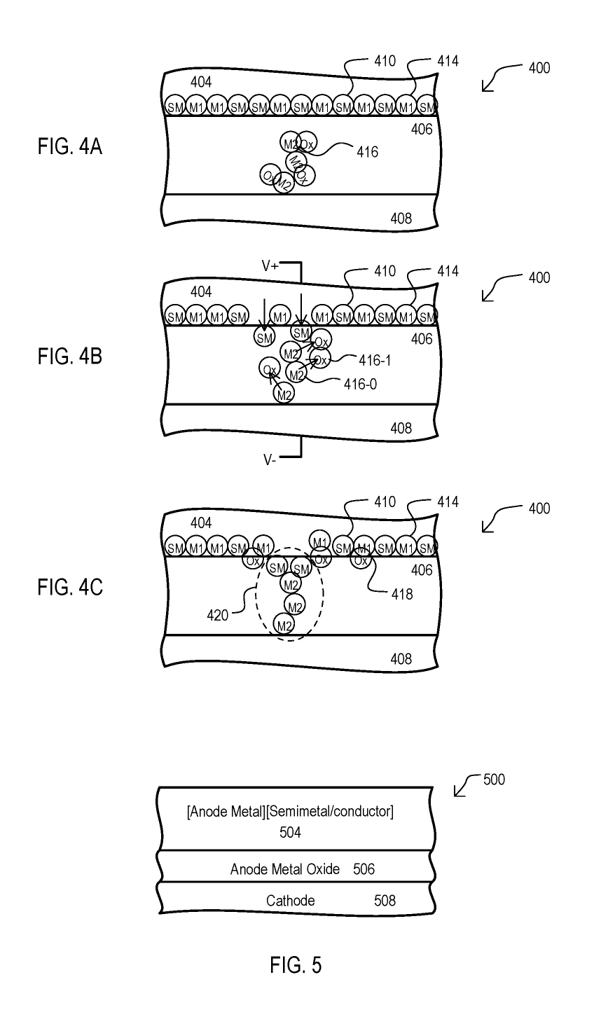

FIGS. 4A to 4C are side cross sectional views representing the formation of a conductive regions within a memory element according to a further embodiment. The embodiment of FIGS. 4A-4C shows an arrangement like that of FIG. 3A to 3D, but with filaments being formed by metal atoms present in a switching layer in addition to semimetal(s)/semiconductor(s) atoms. In a very particular embodiment, FIGS. 4A to 4C show formation operations for a memory element like that shown in FIG. 1.

FIG. 4A shows a memory element prior to the application of an electric field. A first electrode 404 can be an anode, and can include semimetal(s)/semiconductor(s) atoms (shown as SM) as well as anode metal atoms (shown as M1). Very little or none of the semimetal(s)/sem iconductor(s) (SM) that can form a conductive structure within the switch layer can be present in the switch layer 406.

A switch layer 406 can be formed of, or include, one or more switch metal oxide molecules/compounds (one shown as 416). Such a switch metal oxide can include a switch oxide metal (M2) and one or more oxygen atoms (Ox). In some embodiments, a switch oxide metal (M2) can be different from an anode metal (M1).

However, in other embodiments, a switch oxide metal can be the same as an anode metal (i.e., M2=M1).

FIG. 4B shows the application of one or more electric field across the electrodes 404/408. In response, semimetal(s)/semiconductor(s) 410 can move out of the first electrode 404 (i.e., anode) into the switch layer 406. In addition, oxygen atoms (one shown as 416-1) can be freed from the switch metal oxide leaving a switch oxide metal atom (one shown as 416-0).

FIG. 4C shows the formation of a conductive region 420 through switch layer 406. As shown, a portion of a conductive region 420 can be formed by the semimetal(s)/semiconductor(s) (SM), while another portion can be formed by switch oxide metal atoms (M2). In addition, in some embodiments, oxygen freed from the switch metal oxide can form an oxide with the anode metal to form an anode oxide (shown as 418).

Electric field(s) opposite to that of FIG. 4B can be applied to essentially reverse the operations shown in FIGS. 4B and 4C to return an element to a state like that of FIG. 4A.

It is understood that FIGS. 4A to 4C are but diagrammatic representations of operation. Actual position or states of semimetal(s)/sem iconductor(s) atoms and/or compounds can take various forms.

FIG. 5 is a side cross sectional view of a memory cell 500 according to another embodiment. A first electrode 504 can be a mix of one or more anode metals and one or more semimetal(s)/semiconductor(s). In some embodiments, a first electrode 504 can be a binary alloy of one anode metal and one semimetal/semiconductor.

A switch layer 506 can include, or be formed entirely of, a metal oxide of the anode metal. In some embodiments, and as described herein, in a programming operation (an operation that forms a conductive region in switch layer 506) oxygen can be freed from the switch layer and bind with the anode metal to form the anode metal oxide at the first electrode 504. A second electrode 408 can be formed of any suitable conductive material(s).

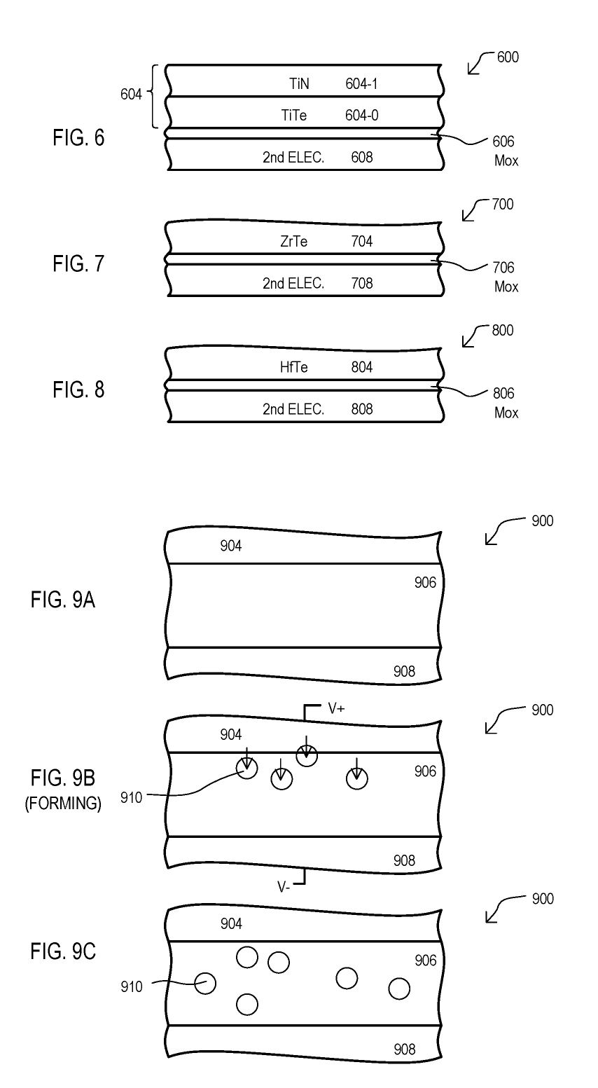

FIG. 6 is a side cross sectional view of a memory cell according to one very particular embodiment. A first electrode 604 can include a layer 604-0 that is a mix of a metal and a semimetal(s)/semiconductor(s). Layer 604-0 can be in direct contact with a switch layer 606. In one particular embodiment, layer 604-0 can include the metal titanium (Ti) and the semimetal(s)/semiconductor(s) can be Te (i.e., layer 604-0 is a Ti/Te compound).

Referring still to FIG. 6, first electrode 604 can include another conductive layer 604-1 formed on layer 604-0. In one particular embodiment, a layer 604-1 can be titanium nitride (TiN).

In the embodiment shown, switch layer 606 can be a metal oxide. The switch layer 606 can be formed on a second electrode 608. Switch layer 606 and second electrode 608 can be formed of any suitable materials described herein, or equivalents.

FIG. 7 is a side cross sectional view of a memory cell according to another very particular embodiment. A first electrode 704 can include an anode metal of Zr and the semimetal/semiconductor Te (i.e., layer 704 is a Zr/Te compound). Remaining layers (706, 708) can vary according to the various embodiments disclosed herein. In a particular embodiment, switch layer 706 can be formed all, or in part, of ZrOx. However, switch layer 706 and second electrode 708 can be formed of any suitable materials described herein, or equivalents.

FIG. 8 is a side cross sectional view of a memory cell according to another very particular embodiment. A first electrode 804 can include an anode metal of Hf and the semimetal/semiconductor Te (i.e., layer 804 is an Hf/Te compound). Remaining layers (806, 808) can vary according to the various embodiments disclosed herein. In a particular embodiment, switch layer 806 can be formed all, or in part, of HfOx. However, switch layer 706 and second electrode 708 can be formed of any suitable materials described herein, or equivalents.

FIGS. 9A to 9C show a method for creating a memory element 900 according to an embodiment. FIGS. 9A to 9C show a method in which an electrical “forming” step can be used to place semimetal(s)/sem iconductor(s) into a switch layer.

FIG. 9A shows a “fresh” memory element 900. A fresh memory element 900 can be a memory element following physical processing steps, but prior to any electrical testing. That is, the memory element 900 has not been subject to applied electrical biases. Very little or none of the semimetal(s)/semiconductor(s) that can form a conductive structure within the switch layer can be present in the switch layer 906.

FIG. 9B shows a “forming” step. A bias can be applied across the electrodes 904/908 of a first polarity. In response, semimetal(s)/sem iconductor(s) 910 can move out of the first electrode 904 (i.e., anode) into the switch layer 906. As in other embodiments shown herein, 910 can represent semimetal(s)/semiconductor(s) atoms, but on other embodiments, semimetal(s)/semiconductor(s) can be compounds of more than one atom.

FIG. 9C shows a memory element 900 following the forming step. Semimetal(s)/semiconductor(s) 910 can be distributed within an insulating switch layer 906. A first electrode 904, switch layer 906 and second electrode 908 can be formed of any suitable materials described herein, or equivalents.

In some embodiments, an element 900 can then be programmed as shown in FIGS. 2A to 2C.

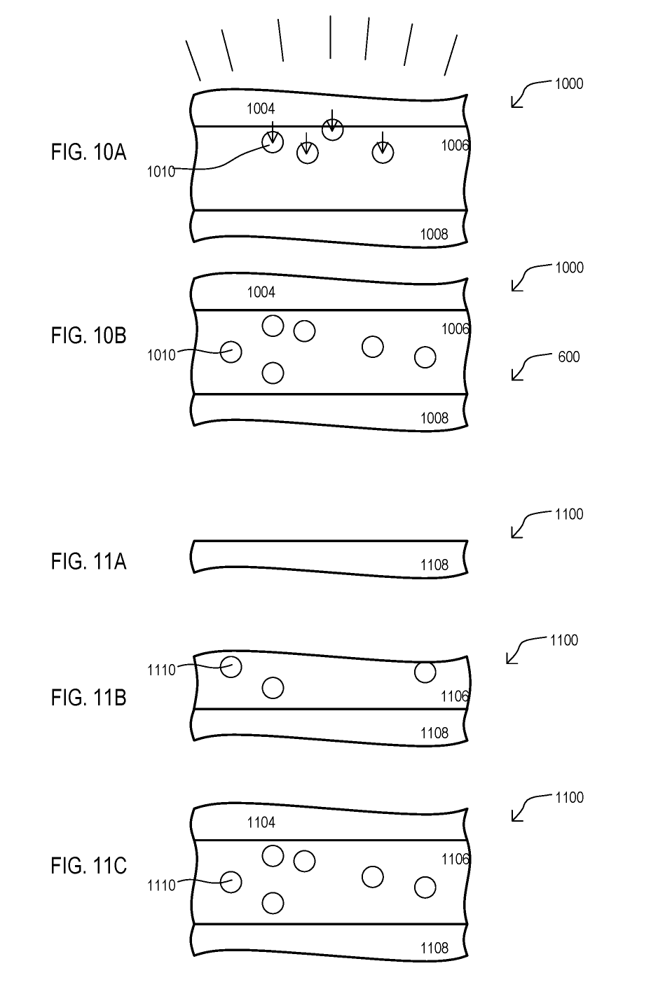

FIGS. 10A and 10B show a method for creating a memory element 1000 according to another embodiment. FIGS. 10A and 10B show a method in which a fabrication step places a semimetal(s)/semiconductor(s) into a switch layer.

FIG. 10A shows an incorporation step for memory element 1000. Prior to such a step, a first electrode 1004 of a memory element can be formed that includes the semimetal(s)/sem iconductor(s) for forming conductive paths through an insulating switch layer 1006. A memory element 1000 can be subject to process treatment that results in semimetal(s)/sem iconductor(s) 1010 moving out of the first electrode 1004 (i.e., anode) and into the switch layer 1006. Such a process treatment can include any of a heat treatment, a chemical treatment, and/or a light treatment. As in other embodiments shown herein, 1010 can represent semimetal(s) /semiconductor(s) atoms, but on other embodiments, semimetal(s)/semiconductor(s) can be compounds of more than one atom.

FIG. 10B shows a memory element 1000 following the treatment step. Semimetal(s)/semiconductor(s) 1010 can be distributed within an insulating switch layer 1006.

In some embodiments, an element 1000 can then be programmed as shown in FIGS. 2A to 2C.

FIGS. 11A to 11C shows a method for creating a memory element 1100 according to another embodiment. FIGS. 11A to 11C shows a method in which semimetal(s) /semiconductor(s) can be formed in situ within switch layer.

FIG. 11A shows the formation of a second electrode 1108.

FIG. 11B shows the formation of a switching layer 1106 that includes semimetal(s)/semiconductor(s) 1110.

FIG. 11C shows the formation of a first electrode 1104. Sem imetal(s)/semiconductor(s) 1110 can be distributed within an insulating switch layer 1106.

The various structures of FIGS. 11A to 11C can be formed of elements according to any of the embodiments herein, or equivalents.

In some embodiments, an element 1100 can then be programmed as shown in FIGS. 2A to 2C.

It is noted that while embodiments show layers with a particular vertical orientation, alternate embodiments can have a different orientation. As but one example, an insulating material can be formed over a layer containing the semi-metal and/or semiconductor that can form a conductive structure. Further, other embodiments can have a lateral arrangement, with an insulating layer having a vertical orientation between a layer containing the semi-metal and/or semiconductor that can form a conductive structure.

It should be appreciated that reference throughout this description to “one embodiment” or “an embodiment” means that a particular feature, structure or characteristic described in connection with the embodiment is included in at least one embodiment of an invention. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the invention.

It is also understood that other embodiments of this invention may be practiced in the absence of an element/step not specifically disclosed herein.

Similarly, it should be appreciated that in the foregoing description of exemplary embodiments of the invention, various features of the invention are sometimes grouped together in a single embodiment, figure, or description thereof for the purpose of streamlining the disclosure aiding in the understanding of one or more of the various inventive aspects. This method of disclosure, however, is not to be interpreted as reflecting an intention that the claims require more features than are expressly recited in each claim. Rather, inventive aspects lie in less than all features of a single foregoing disclosed embodiment. Thus, the claims following the detailed description are hereby expressly incorporated into this detailed description, with each claim standing on its own as a separate embodiment of this invention.

What is claimed is:

1. A memory element programmable between different impedance states, comprising:
a first electrode layer comprising a semimetal or semiconductor (semimetal/sem iconductor) and at least one other first electrode element;
a second electrode; and
a switch layer formed between the first and second electrodes and comprising an insulating material; wherein
atoms of the semimetal/semiconductor provide a reversible change in conductivity of the switch layer by application of electric fields.

2. The memory element of claim 1, wherein:
the semimetal/sem iconductor is selected from the group of: (C) Carbon, (Te) Tellurium, (Sb) Antimony, (As) Arsenic, (Ge) Germanium, (Si) Silicon, (Bi) Bismuth, (Sn) Tin, (S) Sulfur, (Se) Selenium, for example.

3. The memory element of claim 1, wherein:
the at least one other first electrode element is a transition metal selected from any of groups (columns) 3-8 of the periodic table.

4. The memory element of claim 3, wherein:
the semimetal/semiconductor is tellurium.

5. The memory element of claim 3, wherein:
the at least one other first electrode element is a transition metal selected from any of groups (columns) 3-6 of the periodic table.

6. The memory element of claim 1, wherein:
the at least one other first electrode element is selected from the group of: (Sc) Scandium, (Y) Yttrium, (Ti) Titanium, (Zr) Zirconium, (Hf) Hafnium, (V) Vanadium, (Nb) Niobium, (Ta) Tantalum, (Cr) Chromium, (Mo) Molybdenum, (W) Tungsten, and (Lu) Lutetium.

7. The memory element of claim 1, wherein:
the first electrode element comprises about 25-75 atomic percent of the other first electrode element.

8. The memory element of claim 7, wherein:
the first electrode element comprises about 30-60 atomic percent of the other first electrode element.

9. The memory element of claim 8, wherein:
the other first electrode element is selected from the group of: (Ti) Titanium, (Zr) Zirconium and (Hf) Hafnium.

10. The memory element of claim 7, wherein:
the first electrode element comprises about 30-50 atomic percent of the other first electrode element.

11. The memory element of claim 10, wherein:
the other first electrode element is selected from the group of: (Cr) Chromium, (Mo) Molybdenum and (W) Tungsten.

12. The memory element of claim 7, wherein:
the first electrode element comprises about 40-60 atomic percent of the other first electrode element.

13. The memory element of claim 12, wherein:
the other first electrode element is selected from the group of: (V) Vanadium, (Nb) Niobium and (Ta) Tantalum.

14. The memory element of claim 1, wherein:
an atomic percent ratio between the semimetal/sem iconductor to the other first electrode element is in the range of about 0.33-3.0.

15. The memory element of claim 14, wherein:
an atomic percent ratio between the semimetal/sem iconductor to the other first electrode element is in the range of about 0.43-1.5.

16. The memory element of claim 15, wherein:
the other first electrode element is selected from the group of: (Ti) Titanium, (Zr) Zirconium and (Hf) Hafnium.

17. The memory element of claim 14, wherein:
an atomic percent ratio between the semimetal/sem iconductor and the other first electrode element is in the range of about 0.67-1.5.

18. The memory element of claim 15, wherein:
the other first electrode element is selected from the group of: (V) Vanadium, (Nb) Niobium and (Ta) Tantalum.

19. The memory element of claim 14, wherein:
an atomic percent ratio between the semimetal/sem iconductor and the other first electrode element is in the range of about 0.43-1.0.

20. The memory element of claim 19, wherein:
the other first electrode element is selected from the group of: (Cr) Chromium and (Mo) Molybdenum.

21. The memory element of claim 1, wherein the switch layer comprises at least oxygen.

22. The memory element of claim 21, wherein the switch layer further comprises at least one other switch layer element.

23. The memory element of claim 22, wherein:
the at least one other switch layer element is the same as the at least one other first electrode element.

24. The memory element of claim 22, wherein:
the at least one other switch layer element is an alkali earth metal, transition metal, post transition metal, or metalloid selected from groups (columns) 2-6 and 13-16 of the periodic table.

25. The memory element of claim 22, wherein:
the at least one other switch layer element is selected from the group of: (Mg) Magnesium, (Ca) Calcium, (Sr) Strontium, (Sc) Scandium, (Y) Yttrium, (Ti) Titanium, (Zr) Zirconium, (Hf) Hafnium, (V) Vanadium, (Nb) Niobium, (Ta) Tantalum, (Mo) Molybdenum, (W) Tungsten, (Al) Aluminum, (Si) Silicon, (Ge) Germanium, (Te) Tellurium, and (Lu) Lutetium.

26. The memory element of claim 22, wherein:
the at least one other switch layer comprises a binary oxide of the other switch layer element.

27. The memory element of claim 26, wherein:
the stoichiometry of the binary oxide is MₓO_{y}, where M is the other switch layer element and O is oxygen, and the ratio of x:y is in the range of about 1:0.8 to 1:3.2.

28. The memory element of claim 26, wherein:
the other switch layer element is selected from groups (columns) 2-6 of the periodic table.
